(19) United States
(12) Patent Application Publication
(10) Pub. No.: US 2026/0135063 A1
(43) Pub. Date: May 14, 2026

(54) BEAM CONDITIONING FOR DEFECT CONTROL IN BEAMLINE ION IMPLANTER

(71) Applicant: Applied Materials, Inc., Santa Clara, CA (US)

(72) Inventors: Bon-Woong Koo, Andover, MA (US); Alexandre Likhanskii, Malden, MA (US); Tseh-Jen Hsieh, Rowley, MA (US); Gregory E. Stratoti, Haverhill, MA (US); Saurabhsinh Dipaksinh Parmar, Navsari (IN); Paul J. Murphy, Reading, MA (US)

(73) Assignee: Applied Materials, Inc., Santa Clara, CA (US)

(21) Appl. No.: 18/999,759

(22) Filed: Dec. 23, 2024

Related U.S. Application Data
(60) Provisional application No. 63/719,866, filed on Nov. 13, 2024.

(51) Int. Cl. H01J 37/317; H01J 37/304

(52) U.S. Cl. CPC H01J 37/3171; H01J 37/304; H01J 2237/0225; H01J 2237/057; H01J 2237/31705

(57) ABSTRACT

A method of reducing defects in a beamline ion implanter. The method may entail, after performing an implantation procedure on a set of substrates disposed in a process chamber of a beamline of the ion implanter, using a first ion beam comprising a first ion species, the additional procedure of: performing a beam conditioning operation of at least a portion of the beamline. The beam conditioning operation may include generating a second ion beam and conducting the second ion beam to the process chamber along a direction of propagation, and moving the second ion beam within the process chamber, in a sweep direction, at an angle with respect to the direction of propagation, wherein a targeted region of the process chamber is impacted by the second ion beam.

### RELATED APPLICATIONS

This application claims priority to U.S. provisional patent application Ser. No. 63/719,866, filed Nov. 13, 2024, entitled ‘Beam Conditioning for Defect Control In Beamline Ion Implanter,’ the contents of which patent application are incorporated by reference herein in their entirety.

### FIELD

The present embodiments are related to ion implanters, and in particular to beamline ion implanters.

### BACKGROUND

Beamline ion implanters are used to implant ion species into a substrate, often at ion energies of several hundred eV up to 10 MeV or higher. In one widespread application, beamline ion implanters are used to implant dopant ions into a semiconductor substrate (wafer). One of the recent semiconductor process trends includes an increased number of dedicated high-dose implant applications. Such applications may entail implanting the same dopant species over thousands of wafers in a sequential manner. Such dedicated species implantation approach, either conducted at relatively lower ion energy or relatively higher ion energy, may tend to cause the formation of beam-induced deposit layers derived from dopant ions in different regions of the beamline. Particularly heavy layers may accumulate in areas close to the wafer being implanted. These layers may tend to flake because of thermal cycling, stress buildup, and so forth, resulting in unwanted effects, such as (1) particle excursion, (2) beam glitching and (3) divot defect formation, for example. These effects, in turn, may cause excessive wafer failure, in terms of meeting product specifications.

To address the problem of defect formation caused by deposited layers, preventative maintenance may be performed at scheduled intervals before layer thickness of deposited dopants becomes too thick and defection formation becomes excessive. This scheduled maintenance may affect productivity and throughput, resulting in undue cost for processing wafers.

It is with respect to these and other considerations that the present improvements may be useful.

### BRIEF DESCRIPTION OF THE DRAWINGS

FIG. 1A illustrates an embodiment of an ion implanter;

FIG. 1B depicts components of an exemplary controller;

FIG. 2A depicts an exemplary ion implanter in one mode of operation;

FIG. 2B depicts the ion implanter of FIG. 2A in another mode of operation;

FIG. 3A illustrates a side view of an exemplary ion implanter in one example of operation in ion implantation mode;

FIG. 3B illustrates a side view of the exemplary ion implanter of FIG. 3A in a beam measurement instance;

FIG. 4A illustrates a side view of a portion of another exemplary ion implanter in a beam conditioning mode of operation;

FIG. 4B illustrates a side view of the exemplary ion implanter of FIG. 4A in a beam conditioning mode of operation;

FIG. 5A depicts a side view of an ion implanter during an implantation operation;

FIG. 5B depicts a close-up top view of a substrate after implantation in the ion implanter of FIG. 5A;

FIG. 6A and FIG. 6B present experimental results showing defect accumulation during ion implantation of multiple substrates, according to a known implant procedure;

FIG. 6C and FIG. 6D present experimental results showing defect accumulation during ion implantation of multiple substrates, using an approach that includes beam conditioning, according to the present embodiments; and

FIG. 7 presents an exemplary process flow.

### DETAILED DESCRIPTION

A beam conditioning approach for decreasing defects in a beamline ion implanter is presented herein.

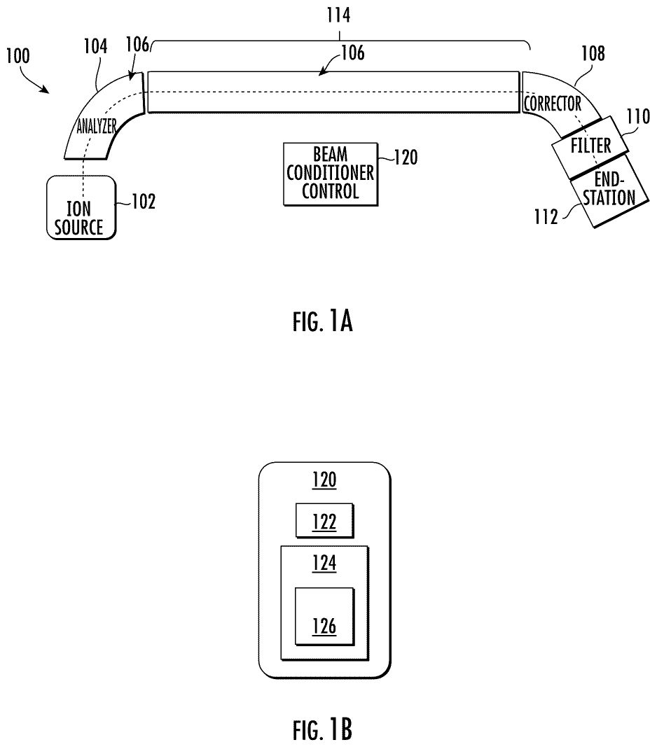

FIG. 1A depicts a schematic of an ion implanter apparatus, according to embodiments of the disclosure. The ion implanter 100, may represent a beamline ion implanter, with some elements not shown for clarity of explanation. The ion implanter 100 may include an ion source 102, as known in the art. The ion source 102 may include an extraction system including extraction components and filters (not shown) to generate an ion beam 106 at a first energy. Examples of suitable ion energy for the first ion energy range from 5 keV to 300 keV, while the embodiments are not limited in this context.

The ion implanter 100 may include an analyzer 104, functioning to analyze the ion beam 106 as in known apparatus, by changing the trajectory of the ion beam 106, as shown. The ion implanter may further include components such as a corrector 108, energy filter 110 and end station 112, as known in the art. The ion implanter 100 may include additional beamline components as known in the art, where additional components are represented by beamline components 114. These beamline components may include mass analysis slits, scanners, quadrupoles, or other elements, according to different non-limiting embodiments. Such components may be used to shape, steer, and accelerate, or decelerate the ion beam 106.

During an implantation mode of operation, the ion implanter 100 may implant a selected ion species into a substrate located in the end station 112. In some examples, the ion implanter may perform a dedicated implantation using the same ion species for multiple consecutive wafers (substrates). In some instances the dedicated implantation may be performed for 500 consecutive wafers, 1000 consecutive wafers, 2000 consecutive wafers, and so forth.

The ion implanter 100 may also be operated in a beam conditioning mode, where an ion beam is directed through the ion implanter and towards the end station 112 to perform a beam conditioning operation, as detailed hereinbelow. A beam conditioner control element, referred to as controller 120, may be provided to schedule and manage the beam conditioning operation.

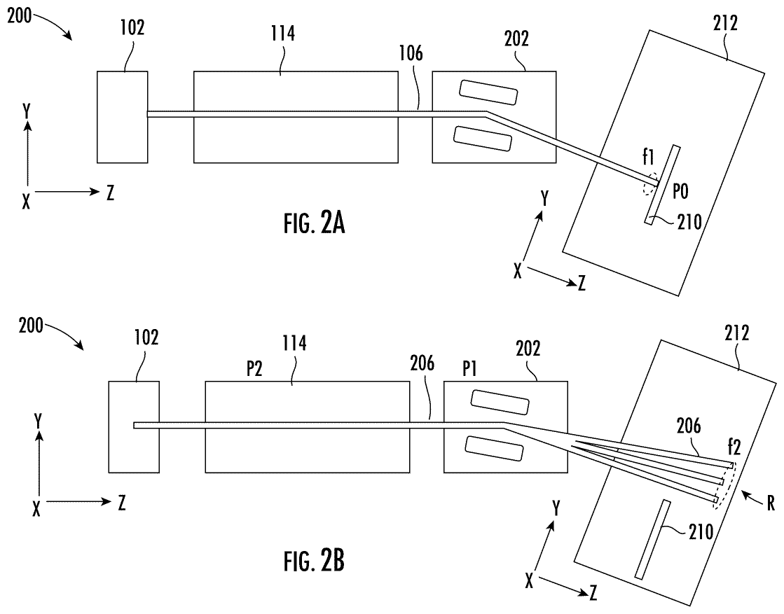

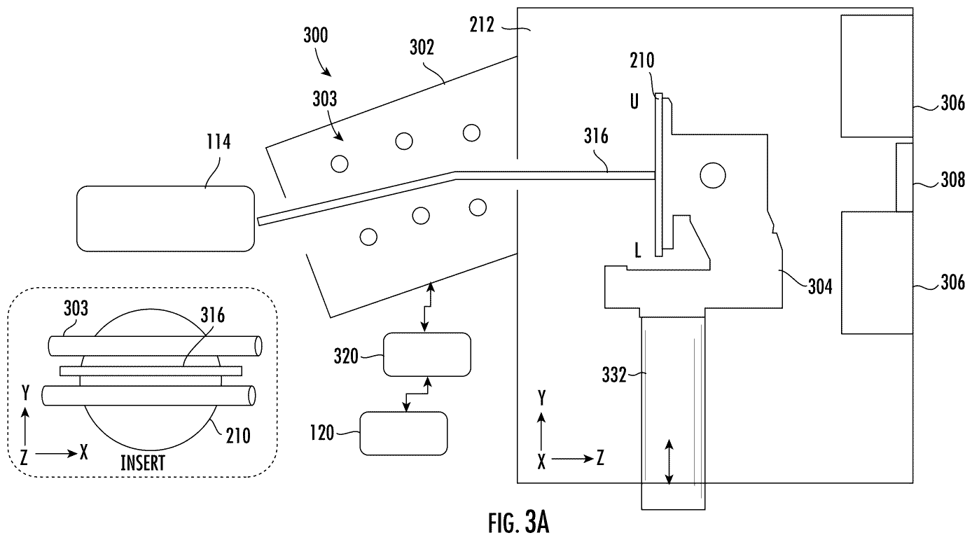

Turning to FIG. 2A there is shown another exemplary ion implanter in one mode of operation. The ion implanter 200 may include an ion source 102 as well as beamline components 114, as discussed above with respect to FIG. 1A, such as analyzer and corrector, are omitted. The ion implanter 200 also includes an energy filter 202 that is upstream to a process chamber 212, while being disposed downstream of other beamline components, as represented by beamline components 114. Note that the process chamber 212 may constitute a portion of an end station 112, where implantation is to take place. The scenario of FIG. 2A depicts an implantation mode of operation, where the ion beam 106 is formed of an implant species, such as boron ion, phosphorous ions, arsenic ions, and so forth. During implantation, the ion beam 106 may be accelerated, decelerated, steered, and shaped, to implant into a substrate 210, located in the process chamber 212.

The ion beam 106 may be maintained to remain stationary along the Y-axis direction during the implantation, as is the case in known implantation procedures. In some examples, the ion beam 106 may be elongated along the X-axis so as to cover an entirety of the substrate 210 along the X-axis direction, either as a static ribbon beam or a scanned spot beam. To implant an entirety of the substrate 210, the substrate 210 may be scanned along the Y-direction while exposed to the elongated (along the X-axis direction) form of ion beam 106. In embodiments of a scanned spot beam, the ion beam 106 may be scanned rapidly, such as at 1 kHz or higher frequency, along the X-axis, to effectively create an elongated footprint along the X-axis direction. Note that the scanning of the substrate 210 may take place at a rate on the order of 10 Hz, 1 Hz or less, so that ion beam 106 will ‘appear’ to the substrate as a ribbon beam, elongated along the X-axis. In the mode of operation of FIG. 2A the energy filter 202 will act to steer and accelerate/decelerate the ion beam 106 in a static manner, so that the ion beam 106 may be maintained at a fixed position, shown as P0, during ion implantation.

During a sequence of ion beam implantation of substrates, stray ions may impinge on surfaces within the process chamber, such as a substrate holder (not shown). In addition, the substrate 210, as well as a substrate holder (not shown) may be withdrawn so that the ion beam 106 impinges upon other components and other surfaces of the process chamber 212, such as a current or dose monitor. As such, ions of the ion beam 106 may deposit into unwanted surfaces of the process chamber 212. This circumstance may be promoted in the case of high dose and low energy implant processes. As a result, layers formed from depositing implant species may accumulate in the process chamber 212 and may generate defects that propagate onto process wafers, because of flaking of the deposit layers or other processes.

FIG. 2B depicts the ion implanter of FIG. 2A in another mode of operation. This scenario represents a beam conditioning operation. An ion beam 206 is generated and conducted to the process chamber 212. In some examples, the ion beam 206 may be formed of an ion species different than the ion species of ion beam 106, used to implant wafers. In other examples, the ion beam 206 may be the same ion species as the ion beam 206, while at a higher ion energy than ion beam 106. In the operation of FIG. 2B, according to different variants, the ion beam 206 is scanned in a direction at an angle to the direction of propagation (Z-axis) of the ion beam 206, such as along the Y-axis, or scanned along the X-axis, or scanned along both the X-axis and the Y-axis. In particular embodiments, the ion beam 206 is directed to a targeted region of the process chamber 212, such as a region R where condensed layers formed from ion species in prior implantation runs are deposited. Because the ion beam 206 is not stationary, and is swept along the Y-axis, for example, the ion beam 206 may impinge on a larger area of the process chamber 212 as compared to ion beam 106. As a result, the footprint f2 of ion beam 206 is larger than the footprint of f1 of ion beam 106. In various embodiments, the ion beam 206 may act to coat existing accumulated layers formed by ion beam 106, or to react with and remove such layers, or to sputter away such layers.

According to various embodiments, the energy filter 202 may be an electrostatic filter having electrodes that receive voltage signals to guide and accelerate or decelerate the ion beam 206. In the beam conditioning mode of operation, the ion beam 206 may be scanned by dynamically varying different voltages that are applied to electrodes of the energy filter 202 at position P1, just upstream of the process chamber 212.

In other embodiments, the ion beam 206 may be scanned at locations further upstream in the beamline, such as at position P2. For example, quadrupole elements may be used to scan the ion beam 206 at location P2, where the scanning of the ion beam 206 may intercept other surfaces of the beamline, so as to treat these other surfaces in a manner similar to the scenario of FIG. 2B.

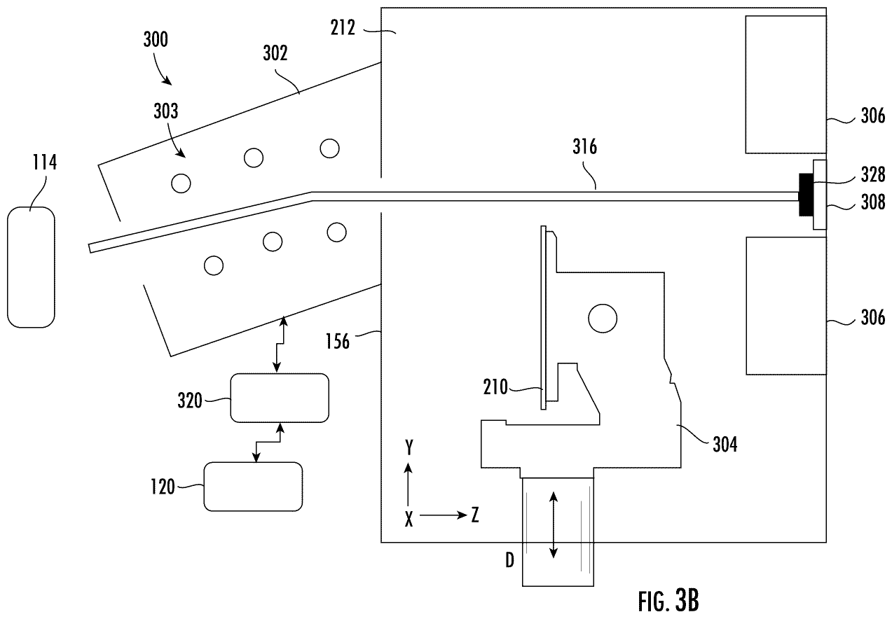

FIG. 3A illustrates a side view of an exemplary ion implanter during operation in ion implantation mode. The ion implanter 300 includes beamline components 114, as discussed previously, including an ion source to generate the ion beam 316. In this embodiment, an electrostatic filter 302 is provided proximate to the process chamber 212. The electrostatic filter may act to modify the energy of the ion beam 316, such as to decelerate and or accelerate, ion beam 316, as well as to shape and steer the ion beam 316, including changing the trajectory of the ion beam 316. In one embodiment, the ion beam 316 may be provided to the electrostatic filter 302 as a ribbon beam, elongated along the X-axis. As such, the electrostatic filter 302 may include an electrode assembly 303 that has a plurality of electrodes that are elongated along the X-axis, in order to extend above and below the ion beam 316, along the X-axis, as shown in the insert.

During ion implantation, a voltage supply assembly 320 is provided to supply a set of voltages to the different electrodes of electrode assembly 303, in order to establish suitable electric fields in the electrostatic filter 302 to provide the proper beam energy, beam steering, beam shaping, focusing, as well as energy filtering of ion beam 316.

The ion beam 316 is directed from the electrostatic filter into process chamber 212, and to substrate 210, which substrate is supported and movable using a substrate holder 304. In one implementation, the substrate holder 304 may be moved at least along the Y-axis of the Cartesian coordinate system shown, such as scanning back and forth along opposite trajectories that are parallel to the Y-axis. In embodiments where the ion beam 316 is a ribbon beam, the substrate 210 may be scanned under the ion beam 316 from an upper end U to a lower end L, in order to cover the substrate 210.

In various embodiments, a series of substrates may be implanted as shown in FIG. 3A, one after another. In some examples, a series of substrates may be implanted over an extended implantation period of operation, such as for 100 hours, 200 hours, or more. As such, up to several hundred wafers or up to a few thousand wafers may be implanted over an extended period of ion implantation. In some non-limiting embodiments, the implant energy for ion beam 316 may be relatively low, such as less than 20 keV, less than 10 keV, or less than 5 keV. In some non-limiting embodiments, the ion beam 316 may be formed of boron-containing ions, such as B⁺ ions. In some non-limiting embodiments, the implant operation for ion beam 316 may deliver an implant dose to substrate 210 that is relatively higher, such as 1E15/cm², 2 E15 Cm/², 5E15/cm², 1E16/cm².

FIG. 3B illustrates a side view of the exemplary ion implanter of FIG. 3A in a beam measurement mode of operation. During an ion implantation period, beam measurements may be occasionally performed, such as at regular periodic intervals. These beam measurements may include measurements, where a substrate 210 is not being implanted, and where the ion beam 316 is directed to a monitor, such as a beam monitor 308, which monitor may act as a dose cup to determine an ion dose that is being delivered to the substrate position, for example. In the embodiment of FIG. 3B, the beam monitor 308 is arranged to intercept the ion beam 316 at a stationary location in the process chamber 212. When such beam measurements by beam monitor 308 are repeated over hundreds or thousands of measurements, ion species from ion beam 316 may accumulate on the surface of the beam monitor 308 as a condensed layer 328.

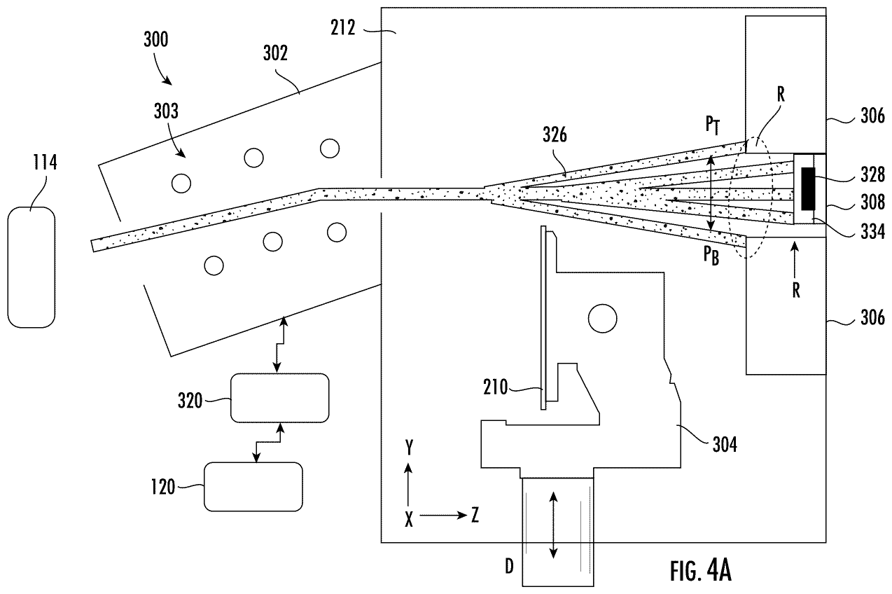

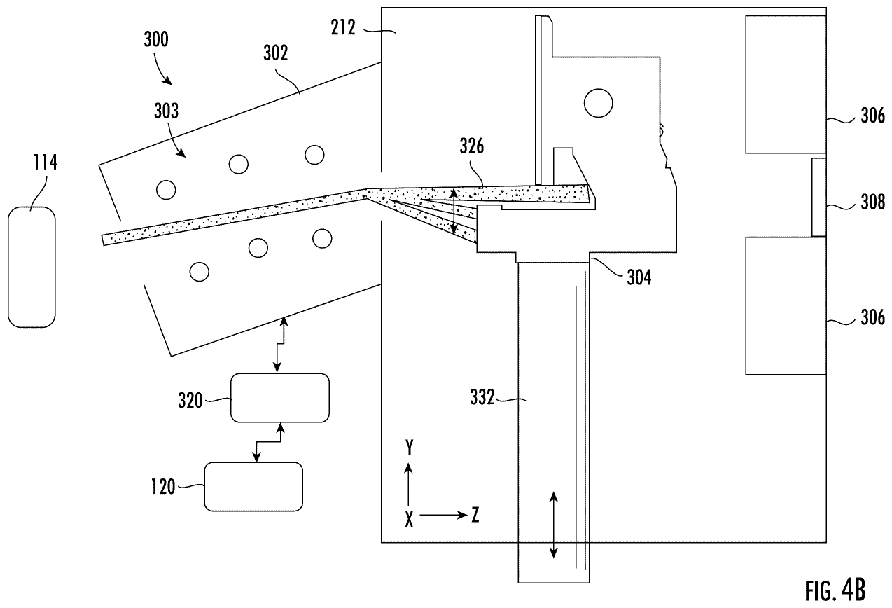

FIG. 4A illustrates a side view of a portion of the ion implanter of FIG. 3A in one variant of a beam conditioning mode of operation. According to embodiments of the disclosure, the ion implanter 300 may be occasionally switched to a beam conditioning mode of operation. In the example, of FIG. 4A. In this mode of operation, another ion beam is generated by ion implanter 300. In this case, a conditioning ion beam 326 may comprise a different ion species than the ion species of ion beam 316, used for ion implantation. Examples of suitable species for the conditioning ion beam 326 include an inert gas ion species, a reactive ion species, or another dopant ion species, such as arsenic, in the case where ion beam 316 is a boron ion beam.

In the operation of FIG. 4A, the conditioning ion beam 326 may enter the electrostatic filter 302 as a continuous, static, ion beam. The controller 120 may send control signals to the voltage supply assembly 320 to dynamically vary a set of voltages applied to at least some of the electrodes of electrode assembly 303. In this manner, the electric fields that are formed within the electrostatic filter 302 may be caused to vary with time as the conditioning ion beam 326 traverses and exits the electrostatic filter 302. This time variation of electric fields may be controlled in a manner to sweep the conditioning ion beam 326, as shown, along the Y-axis, for example. The conditioning ion beam 326 may be swept over number of cycles from a top position P_{T} to a bottom position P_{B} at a relatively slow rate, such as 1 Hz to several Hz, to tens of Hz, to hundreds of Hz. In particular, the operation of FIG. 4A may be performed to target a particular area or region of the process chamber 212, where condensed layers are believed to be concentrated. This region is shown as region R in FIG. 4A, which region may include a “dose cup region” where the beam monitor 308 is located.

In the example where the condensed layer 328 is a boron layer, formed after an extended period of boron ion implantation, the conditioning ion beam 326 may be arsenic. In one example, during a beam conditioning operation, the conditioning ion beam 326 may be swept over regions of the process chamber 212 for an extended duration, such as several minutes up to one hour or more. As such, after a beam conditioning operation, a conditioning layer 334 may form, which layer may interact with, or coat, the condensed layer 328.

According to some embodiments, the operations of ion implantation and beam conditioning may be repeated over a number of implant cycles, where each implant cycle includes an ion implantation operation, a beam conditioning operation, as well as optional operations, such as beam measurement operation, as represented in FIGS. 3A-4A. In various embodiments, the cycle period may be arranged to reduce the accumulation of defects that take place on process wafers. In some embodiments, the duration of an implant cycle may be limited to no more than 24 hours, no more than 12 hours, no more than 6 hours. In some embodiments, the duration of a beam conditioning operation within an implant cycle may be limited to no more than 10% of the implant cycle duration.

FIG. 4B illustrates a side view of the exemplary ion implanter of FIG. 3A in another variant of a beam conditioning mode of operation. In this variant, the conditioning ion beam 326 may be provided as generally described with respect to FIG. 4A. A difference in this embodiment is that the geometry of components within the process chamber 212 is arranged differently than in FIG. 4A. In this example, portions of the substrate holder 304 are arranged to intercept the conditioning ion beam 326. Thus, the conditioning ion beam 326 will treat the surfaces of the substrate holder 304 that are exposed to conditioning ion beam 326. Such surfaces may tend to accumulate dopant deposit during extended ion implantation runs, similarly to condensed layer 328.

While in some embodiments the ion species in a beam conditioning ion beam may differ from the ion species used for operation in implantation mode, in other embodiments, the ion species ion implantation mode and ion beam conditioning mode may be the same. In one non-limiting example, ion implantation of boron may be conducted at an ion beam energy of 1 keV to 10 keV, while a beam conditioning mode may generate boron ions having an ion beam energy of 15 keV to 40 keV, and in particular, 20 keV to 30 keV.

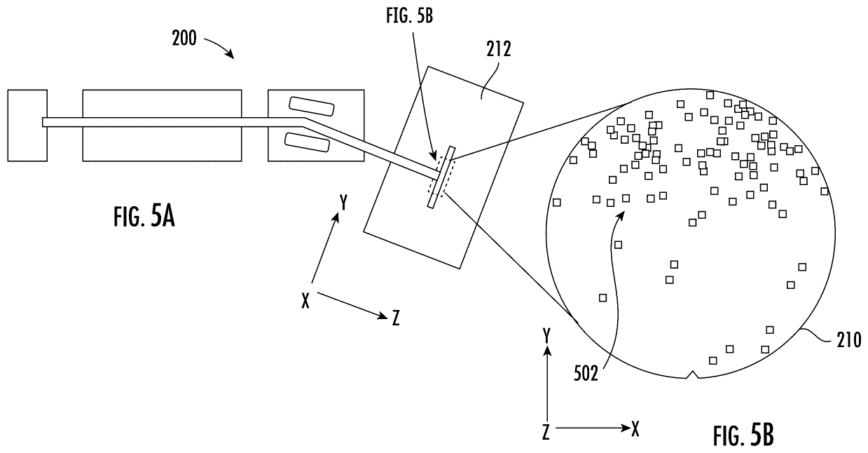

To further explain the efficacy of the present embodiments, FIGS. 5A-5C depict a scenario for defect formation during extended dedicated ion implantation. In particular, FIG. 5A depicts a side view of an ion implanter during an implantation operation, FIG. 5B depicts a close-up top view of a substrate after implantation in the ion implanter of FIG. 5A. The ion implanter may represent ion implanter 200, discussed above. During an extended period of time, the ion implantation process of FIG. 5A may be performed over multiple wafers, where regions of process chamber 212 are exposed to an implanting ion beam for many hours, tens of hours, or hundreds of hours, subjecting these regions to possible accumulation of condensing layers formed from the ion species of an implanting ion beam. Note that an individual wafer may be subject to a relatively lower total exposure to an implanting ion beam, and thus a condensing layer will not form on the individual wafer. However, condensing layers may form on other components of process chamber 212 as discussed above. These condensing layers may then function as a source for generating defects that are transported to a wafer being processed.

This result of defect formation is illustrated in FIG. 5B, where a schematic illustration is presented to show defects 502 that form on a wafer surface of the substrate 210. Note that the defects may be microscopic or nanoscopic in dimension, such as on the order of 0.1 micrometer to several micrometers or more. When such defects are present on a wafer surface in a concentration beyond a specified threshold, the device integrity of devices to be formed on the wafer may be threatened, and the wafer may be scrapped as unusable. In particular, examples, the defects may occur in bands, as shown in FIG. 5B. In general, such defects have been observed after ˜200 hours of an implantation run and may exceed a predetermined threshold after ˜250 hours of run (previous hardware).

### Experiments

In a set of experiments, a marathon run was performed to process multiple wafers using B+ ion implantation over a total period of 550 hours. The ion dose per wafer was 8E15/cm², and the ion energy of the implanting ion beam was 3 keV. In one group of wafers, the wafers were implanted according to a standard implant protocol, under the implant conditions specified above without the beam conditioning of the present embodiments. In another group of wafers, the wafers were subject to the same implant conditions, while a beam conditioning operation was performed at regular intervals in addition to the ion implantation operation.

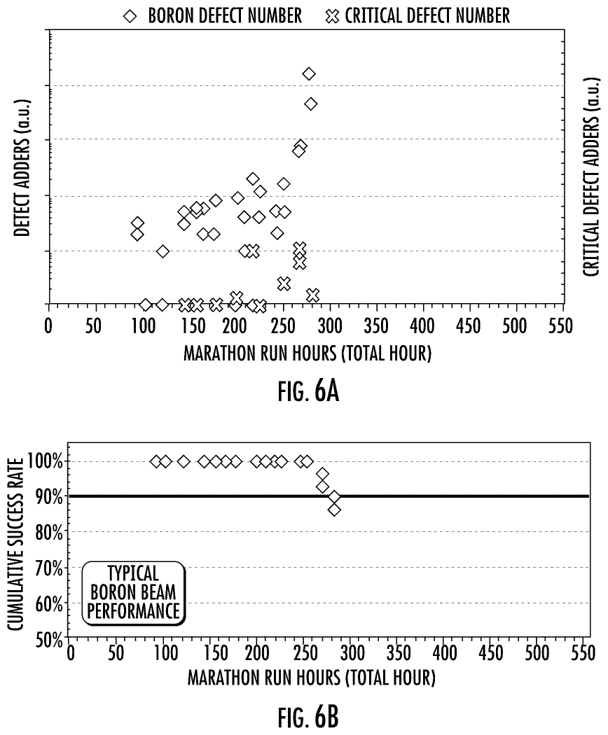

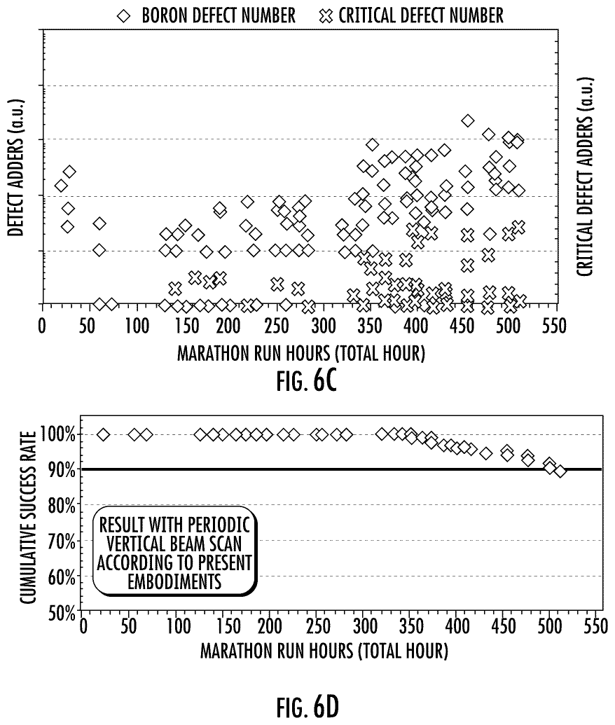

The results of defect analysis of select wafers of the wafers processed according to a standard protocol are shown in FIG. 6A and FIG. 6B. FIG. 6A is a graph depicting the number of total defect adders and the number of divot defects as a function of run time for marathon run. Note that the axis for the total defect adders is arranged on a logarithmic scale. As illustrated in FIG. 6A, the total number of defect adders increases rapidly after approximately 200 hours total run time. The total number of defects exceeds a particle threshold specification of 50 at approximately 250 hours. Likewise, critical defects (defects that may cause device yield loss) become noticeable after approximately 200 hours total run time. In FIG. 6B a metric is shown as cumulative success rate, where 90% represents a threshold, below which value, the wafers are not to be used. Again, the cumulative success rate goes below 90% when total run time exceeds 250 hours.

FIG. 6C presents data for a set of wafers processed with a beam conditioning protocol that is performed at intervals of approximately 12 hours. Thus, in a given implant cycle, ion implantation is conducted for approximately 12 hours, followed by a beam conditioning interval of 30 minutes. The beam conditioning interval was conducted using an arsenic ion beam. In particular, with reference again to FIG. 4A, an arsenic positive ion beam at 20 keV was swept along the Y-axis across an entirety of the recess R that houses the beam monitor 308. As shown, after performing ion implantation that is interspersed with periods of beam conditioning, the value of total defect adders does not substantially exceed 50 until 450 hours total run time, while the number of divot defects does not become substantial till 350 hours. Moreover, as shown in FIG. 6D, the cumulative success rate does not go below 90% until total run time is at least 500 hours.

Without being bound by any theory, the various defects observed on the surface of wafers, especially after extended implantation runs, may be generated from condensed dopant layers that are disposed within a beamline, including in the process chamber 212. One explanation for the reduced defect level observed with respect to FIGS. 6C and 6D using the aforementioned beam conditioning procedure is that the beam conditioning operation generates a protective layer above the condensed layer 328. Thus, the condensed layer 328 may be protected at least in part by conditioning layer 334. In the case of condensed layer 328 being formed by boron, such a layer tends to relatively electrically insulating, and may act as a source of electrical arc generation, creating glitching that leads to explosive particle generation. Arsenic layers will tend to more electrically conductive and may thus reduce the tendency for glitching during ion implantation. Moreover, while the ion implantation protocol may tend to concentrate deposited layers in specific regions of the process chamber, such as in the middle of the recess R, the present inventors have discovered that the use of a sweeping conditioning ion beam that covers a wider footprint than a stationary ion beam is more effective in reducing particle defects.

While the above example involves a conditioning beam that may tend to deposit material over an existing condensed layer, in other embodiments a conditioning beam that removes material, either by sputtering, or reactive etching, may reduce defects by removing or reducing the thickness of a condensed layer.

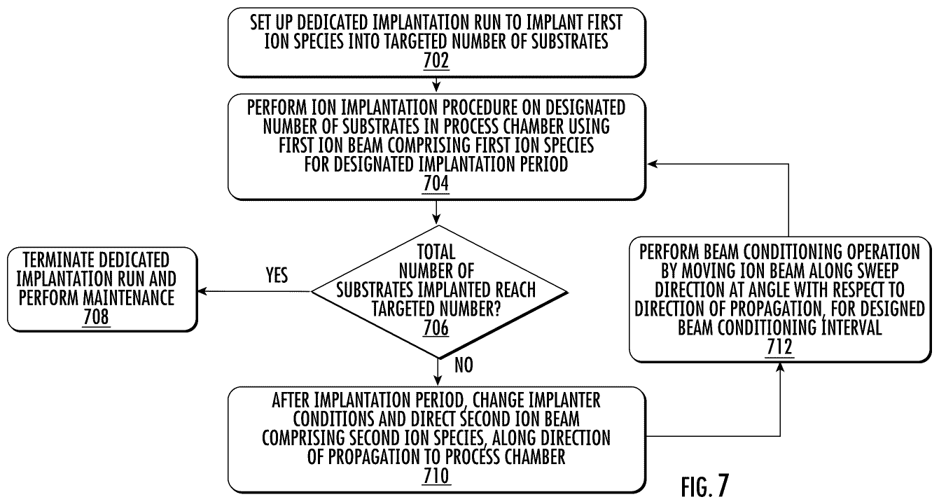

FIG. 7 provides an exemplary process flow 700. At block 702, a dedicated implant run is set up in an ion implanter. The set up may involve setting the targeted recipe for the dedicated implant run and tuning the settings of the ion implanter accordingly. Implementing the dedicated implant run may entail implanting a targeted number of substrates (such as semiconductor wafers) using a given implantation procedure. A given implantation procedure may involve implanting a first ion species, such as boron, where the same implant parameters are used to implant the first ion species into the targeted number of substrates.

At block 704, the ion implantation procedure is performed on a designated number of substrate ions in a process chamber using a first ion beam comprising the first ion species. This ion implantation procedure is carried out for a designated implantation period, such as 6 hours, 12 hours, 24 hours, and so forth. Note that the designated implantation period may be set according to designated time interval, such as 24 hours, or may equivalently be set for a total number of substrates, such as 250 substrates.

At decision block 706, after the designated implantation period, a decision is made as to whether the total number of substrates implanted has reached the targeted number. If so, the process moves to block 708, where the dedicated implantation run is terminated and maintenance scheduled. If not, the process moves to block 710.

At block 710, after the implantation procedure is terminated, a new process implemented, where the implanter conditions are changed, and a second ion beam, comprising a second ion species, such as arsenic, is directed along a direction of propagation into the process chamber.

At block 712, a beam conditioning operation is performed by moving the second ion beam along a sweep direction at an angle with respect to the direction of propagation of the second ion beam. Thus, in one example, the second ion beam may enter the process chamber along a direction of propagation parallel to a Z-axis, while the second ion beam is swept along the Y-axis during the beam conditioning operation. The second ion beam may be directed to sweep over a targeted region of a process chamber where a deposit layer is concentrated. In various non-limiting embodiments, the second ion beam may be swept at a relatively slow rate in a periodic fashion, such as at 0.1 Hz-10 Hz. In some examples, the duration of the beam conditioning interval may be much less than the duration of the designated implantation period, such as less than 10% of the duration of the designated implantation period. As such, the footprint corresponding to the region of impact of the second ion beam within the process chamber may be much larger than the footprint of the second ion beam at any given instance.

The flow then returns to block 704, there the implantation procedure is continued. In this manner the dedicated implantation run may be performed where a series of implantation periods that each implant a targeted number of substrates are interspersed with beam conditioning periods, until the targeted number of wafers are implanted. Alternatively, the dedicated implantation run may be terminated at a decision block 706 based upon a total duration of the dedicated implantation run, such as 500 hours.

Referring again to FIG. 1B, there are shown details of a controller 120, arranged to implement the procedures of the present embodiments as set forth above. In one embodiment, the controller 120 may include a processor 122 or multiple processors, such as a known type of microprocessor, dedicated processor chip, general purpose processor chip, or similar device. The controller 120 may further include a memory or memory unit 124, including multiple memory units, coupled to the processor 122, where the memory unit 124 contains an implantation routine 126. The implantation routine 126 may be operative on the processor 122 to control the ion implanter 100, and in particular to perform the various operations involved in an extended implantation run, including ion implantation operations, and beam conditioning operations, as detailed hereinabove.

The memory unit 124 may comprise an article of manufacture. In one embodiment, the memory unit 124 may comprise any non-transitory computer readable medium or machine readable medium, such as an optical, magnetic or semiconductor storage. The storage medium may store various types of computer executable instructions to implement one or more of logic flows described herein. Examples of a computer readable or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The embodiments are not limited in this context.

In summary, the present embodiments provide a first advantage of increasing productivity of an ion implanter, especially in the case of performing dedicated extended implant runs involving the same implant species. By intermittently performing a beam conditioning procedure interspersed with implantation intervals, the total run time may be extended up to 100% as compared to run times performed by known approaches. As another advantage, embodiments of the present disclosure provide a more efficient manner of maintenance or treating a process chamber during an extended implant run. This advantage occurs since just targeted areas need be treated by a conditioning ion beam, and not the whole process chamber. As another advantage, embodiments of the disclosure that employ scanning a conditioning beam just within the process chamber are safe, in that the conditioning beam may remain stationary upstream of the process chamber, so that particle turbulence along the beamline is avoided.

While the present disclosure makes reference to certain embodiments, numerous modifications, alterations and changes to the described embodiments are possible without departing from the sphere and scope of the present disclosure, as defined in the appended claim(s). Accordingly, it is intended that the present disclosure not be limited to the described embodiments, but that it has the full scope defined by the language of the following claims, and equivalents thereof.

What is claimed:

1. A method of reducing defect formation in an ion implanter, comprising:
performing an implantation procedure using a first ion beam comprising a first ion species, on a set of substrates disposed in a process chamber of a beamline of the ion implanter; and
performing a beam conditioning operation of at least a portion of the beamline, wherein the beam conditioning operation comprises:
generating a second ion beam and conducting the second ion beam to the process chamber along a direction of propagation; and
moving the second ion beam within the process chamber, in a sweep direction, at an angle with respect to the direction of propagation, wherein a targeted region of the process chamber is impacted by the second ion beam.

2. The method of claim 1, wherein the first ion species comprises boron ions, and wherein the second ion beam comprises arsenic ions.

3. The method of claim 1, wherein the first ion beam comprises a dopant species, and wherein the second ion beam comprises a reactive ion species.

4. The method of claim 1, wherein the first ion beam comprises a dopant species, and wherein the second ion beam comprises an inert gas species.

5. The method of claim 1, wherein the beam conditioning operation is conducted by sweeping the second ion beam over a dose cup region of the process chamber.

6. The method of claim 1, wherein the beam conditioning operation is conducted by sweeping the second ion beam over a substrate holder in the process chamber.

7. The method of claim 1, wherein the beam conditioning operation is conducted by sweeping the second ion beam at a rate of 0.1 Hz to 500 Hz.

8. The method of claim 1, wherein the implantation procedure and beam conditioning operation constitute an implant cycle, the method further comprising performing at least one additional implant cycle.

9. The method of claim 8, wherein a duration of the beam conditioning operation is less than 10% of a duration of the implant cycle.

10. The method of claim 1, wherein the performing the beam conditioning operation comprises dynamically varying a set of voltages on an electrostatic filter that is disposed adjacent to the process chamber, while the second ion beam is transported through the electrostatic filter.

11. The method of claim 1, wherein a first footprint of the first ion beam within the process chamber is less than a second footprint of the second ion beam within the process chamber.

12. The method of claim 1, wherein the first ion beam and the second ion beam comprise a same ion species, wherein the first ion beam comprises a first ion energy, and the second ion beam comprises a second ion energy, greater than the first ion energy.

13. The method of claim 1, wherein the sweep direction is a first sweep direction, wherein the beam conditioning operation is conducted by sweeping the second ion beam over the first sweep direction, and further sweeping the second ion beam over a second sweep direction, perpendicular to the first sweep direction.

14. A method of reducing defect formation in an ion implanter, comprising:
intermittently performing a beam conditioning procedure between a series of implantation intervals, wherein the beam conditioning procedure comprises:
generating a conditioning ion beam and conducting the conditioning ion beam to a process chamber along a direction of propagation; and
moving the conditioning ion beam within the process chamber, in a sweep direction, the sweep direction being at an angle with respect to the direction of propagation, wherein a targeted region of the process chamber is impacted by the conditioning ion beam.

15. The method of claim 14, wherein an implantation procedure is performed during the implantation intervals, the implantation procedure comprising:
directing a first ion beam comprising a first ion species, to a set of substrates disposed in the process chamber.

16. The method of claim 14, wherein the beam conditioning operation is conducted by sweeping the conditioning ion beam over a dose cup region of the process chamber.

17. The method of claim 14, wherein the beam conditioning operation is conducted by sweeping the conditioning ion beam over a substrate holder in the process chamber.

18. The method of claim 15, wherein a single implantation procedure and a single beam conditioning operation constitute an implant cycle, wherein a duration of the beam conditioning operation is less than 10% of a duration of the implant cycle.

19. The method of claim 14, wherein the performing the beam conditioning procedure comprises dynamically varying a set of voltages on an electrostatic filter that is disposed adjacent to the process chamber, while the conditioning ion beam is transported through the electrostatic filter.

20. The method of claim 15, wherein a first footprint of the first ion beam within the process chamber is less than a second footprint of the conditioning ion beam within the process chamber.
